(19) United States
(12) Patent Application Publication
(10) Pub. No.: US 2011/0215792 A1
(43) Pub. Date: Sep. 8, 2011

(54) PROBE AND TESTING APPARATUS INCLUDING THE SAME

(75) Inventors: YONG-PING YANG, Shenzhen City (CN); TAI-CHEN WANG, Tu-Cheng (TW)

(73) Assignees: HONG FU JIN PRECISION INDUSTRY ShenZhen) CO., LTD., Shenzhen City (TW); HON HAI PRECISION INDUSTRY CO., LTD., Tu-Cheng (TW)

(21) Appl. No.: 12/796,775

(22) Filed: Jun. 9, 2010

(30) Foreign Application Priority Data
Mar. 3, 2010 (CN) 201010117043.X

(51) Int. Cl. G01R 31/02

(52) U.S. Cl. 324/72.5

(57) ABSTRACT

A probe includes a tip and a body. The tip includes three input terminals and three output terminals. A first output terminal is connected to a first input terminal via a first resistor. A second output terminal is connected to the second input terminal via a second resistor, and connected to the first output terminal via a first switch. A third output terminal is connected to the third input terminal via a third resistor, connected to the first output terminal via a second switch, and connected to the second output terminal via a third switch. The first and second input terminals are operable to receive a pair of differential signals, the third input terminal is grounded.

### BACKGROUND

1. Technical Field

The present disclosure relates to probes and particularly to a probe used in testing apparatuses.

2. Description of Related Art

For quality assurance of computer motherboards, it is necessary to have a differential test and two terminal tests to test a pair of differential signals on the motherboards. The differential test is to test two differential signal lines on a motherboard at the same time. The terminal tests are to test the differential signal lines on the motherboard respectively. Probes for testing an apparatus (e.g. a detector) need to be soldered to contacts on the motherboard to perform the differential test and then be detached therefrom. After the differential test, other probes of the testing apparatus need to be soldered to the motherboard again to perform the two terminal tests. This is time consuming and repeatedly applying solder to the motherboard may degrade the useful life of the motherboard.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of a first embodiment of a probe connected between a motherboard and an oscillograph, wherein the probe includes a tip.

FIG. 2 is a circuit diagram of the tip in FIG. 1.

FIG. 3 is a schematic view of a second embodiment of a probe connected between a motherboard and an oscillograph, wherein the probe includes a tip.

FIG. 4 is a circuit diagram of the tip of FIG. 3.

### DETAILED DESCRIPTION

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

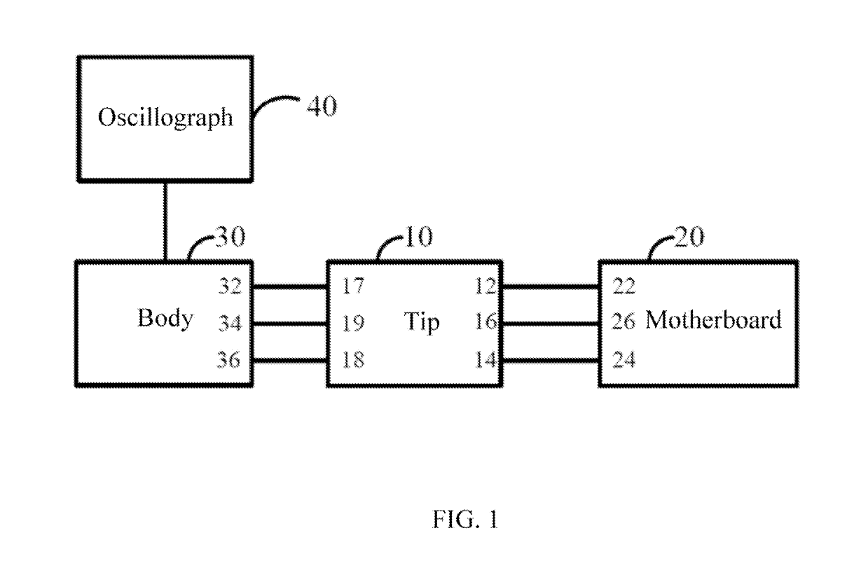

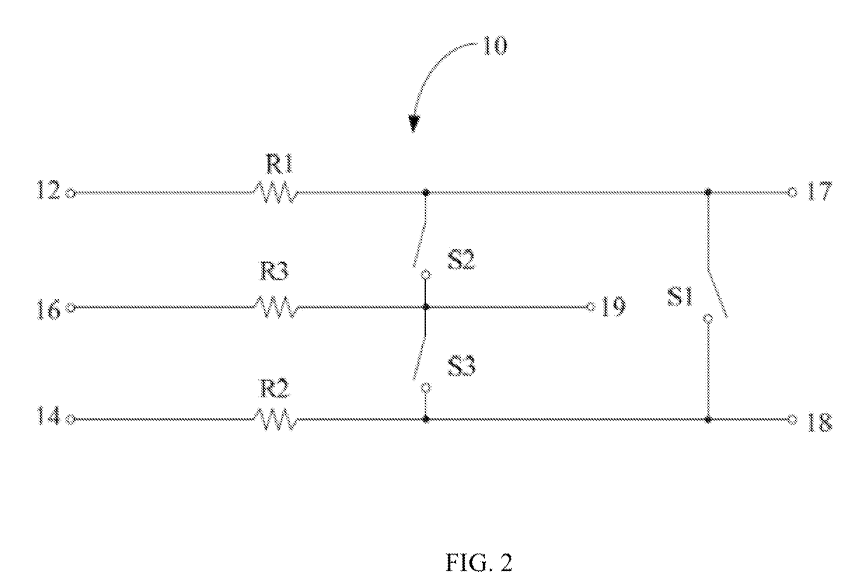

Referring to FIGS. 1 and 2, a first embodiment of a probe for conveniently testing a pair of differential signals includes a tip 10 and a body 30. The tip 10 includes input terminals 12, 14 and 16, and output terminals 17, 18 and 19. The input terminals 12, 14, and 16 are operable to connect contacts 22, 24, and 26 of a motherboard 20 respectively. The output terminals 17, 18, and 19 are operable to connect input terminals 32, 34, and 36 of the body 30 respectively. An output terminal of the body 30 connects to an oscillograph 40. In the embodiment, the contacts 22 and 24 of the motherboard 20 are operable to output the pair of differential signals. The contact 26 of the motherboard 20 is tied to ground. The body 30 transmits the differential signals to the oscillograph 40.

Referring to FIG. 2, the tip 10 includes three switches S1, S2, and S3, and three resistors R1, R2 and R3. The resistor R1 connects between the input terminal 12 and the output terminal 17. The resistor R2 connects between the input terminal 14 and the output terminal 18. The resistor R3 connects between the input terminal 16 and the output terminal 19. The switch S1 connects between the output terminals 17 and 18. The switch S2 connects between the output terminals 17 and 19. The switch S3 connects between the output terminals 18 and 19. The switches S1, S2 and S3 are selectively controlled or operated to have the differential test and the terminal tests.

The input terminals 12, 14, and 16 of the tip 10 connect to the contacts 22, 24, and 26 of the motherboard 20 respectively. When the switch S1 turns on and the switches S2 and S3 turn off, the pair of differential signals from the contacts 22 and 24 of the motherboard 20 is transmitted to the output terminals 17 and 18 of the tip 10. Then, the pair of differential signals is transmitted to the oscillograph 40 via the body 30 to have a difference test for the contacts 22 and 24.

When the switch S2 turns on and the switches S1 and S3 turn off, one of the differential signals from the contact 22 of the motherboard 20 is transmitted to the output terminal 17 of the tip 10 and the oscillograph 40 via the body 30 to have a terminal test for the contact 22 of the motherboard 20.

When the switch S3 turns on and the switches S1 and S2 turn off, the other one of the differential signals from the contact 24 of the motherboard 20 is transmitted to the output terminal 18 of the tip 10 and the oscillograph 40 via the body 30 to have a terminal test for the contact 24 of the motherboard 20.

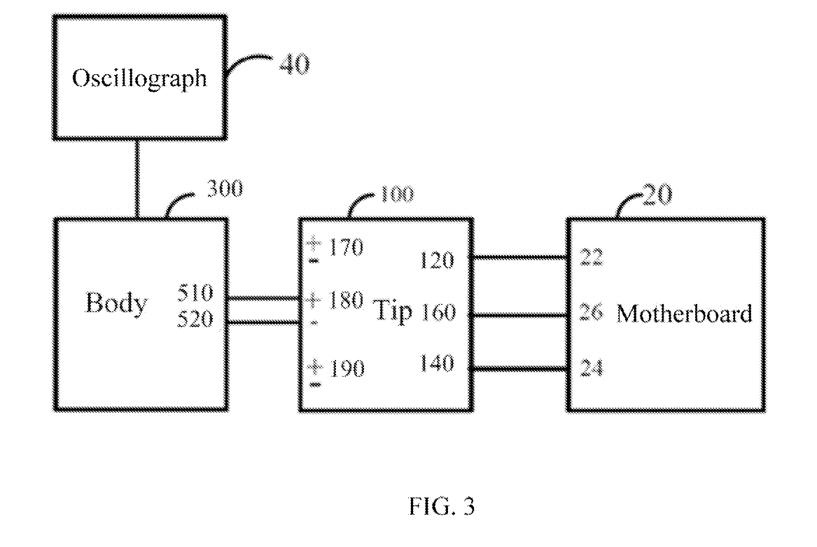

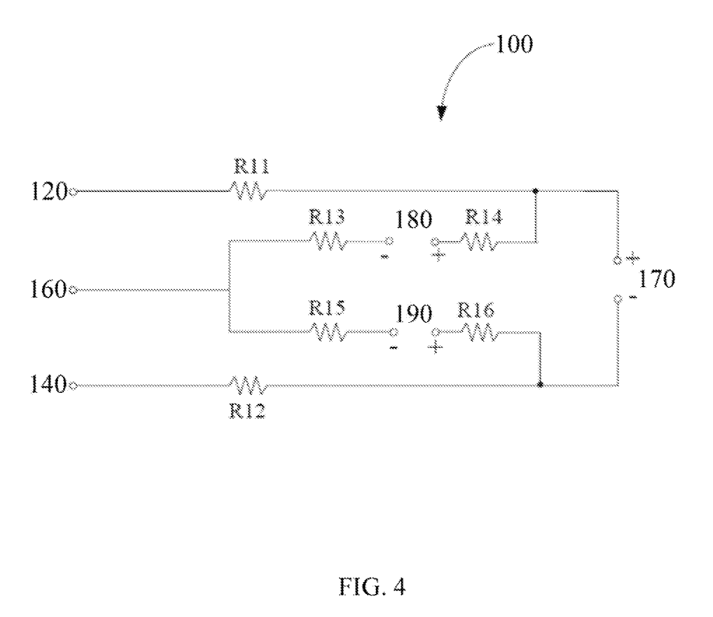

Referring to FIGS. 3 and 4, a second embodiment of a probe includes a tip 100 and a body 300. The body 300 includes two input terminals 510 and 520. The tip 100 includes input terminals 120, 140 and 160, output terminals 170, 180 and 190, and resistors R11, R12, R13, R14, R15, and R16. Each of the output terminals 170, 180, and 190 includes a positive contact “+” and a negative contact “−”.

The resistor R11 connects between the input terminal 120 and the positive contact “+” of the output terminal 170 of the tip 100. The resistor R12 connects between the input terminal 140 and the negative contact “−” of the output terminal 170 of the tip 100. The resistor R13 connects between the input terminal 160 and the negative contact “−” of the output terminal 180. The resistor R14 connects between the positive contacts “+” of the output terminals 170 and 180. The resistor R15 connects between the input terminal 160 and the negative terminals “−” of the output terminal 190. The resistor R16 connects between the positive contact “+” of the output terminal 190 and the negative contact “−” of the output terminal 170. Similarly to the tip 10, the output terminal 170, 180 and 190 of the tip 100 are selectively connected to the body 300 to have the differential test and the terminal tests.

The input terminals 120, 140, and 160 of the tip 100 connect to the contacts 22, 24, and 26 of the motherboard 20 respectively. When the output terminals 180 and 190 of the tip 100 are idle, and the positive contact “+” and the negative contact “−” of the output terminal 170 connect to the input terminals 510 and 520 of the body 300 respectively, the pair of differential signals from the contacts 22 and 24 of the motherboard 20 is transmitted to the oscillograph 40 via the body 300 to have a differential test for the contacts 22 and 24.

When the output terminals 170 and 190 are idle, and the positive contact “+” and the negative contact “−” of the output terminal 180 of the probe 100 connect to the input terminals 510 and 520 of the body 300, one of the differential signals from the contact 22 of the motherboard 20 is transmitted to the oscillograph 40 via the body 300 to perform the terminal test of the contact 22 of the motherboard 20.

When the output terminals 170 and 180 are idle, and the positive contact “+” and the negative contact “−” of the output terminal 190 of the tip 100 connect to the input terminals 510 and 520 of the body 300, another one of the differential signals from the contact 24 of the motherboard 20 is transmitted to the oscillograph 40 via the body 300 to have the terminal test of the contact 24 of the motherboard 20.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A probe for testing a pair of differential signals of a motherboard, the probe comprising:
a body; and
a tip comprising:
a first input terminal;
a second input terminal;
a third input terminal;
a first output terminal connected to the first input terminal via a first resistor;
a second output terminal connected to the second input terminal via a second resistor, and connected to the first output terminal via a first switch; and
a third output terminal connected to the third input terminal via a third resistor, connected to the first output terminal via a second switch, and connected to the second output terminal via a third switch;
wherein the first and second input terminals are operable to receive the differential signals, the third input terminal is grounded.

2. A probe for testing a pair of differential signals of a motherboard, the probe comprising:
a body; and
a tip comprising:
a first input terminal;
a second input terminal;
a third input terminal;
a first output terminal comprising a positive contact and a negative contact, wherein the positive contact of the first output terminal is connected to the first input terminal via a first resistor, the negative contact of the first output terminal is connected to the second input terminal via a second resistor;
a second output terminal comprising a positive contact and a negative contact, wherein the negative contact of the second output terminal is connected to the third input terminal via a third resistor, the positive contact of the second output terminal is connected to the positive contact of the first output terminal via a fourth resistor; and
a third output terminal comprising a positive contact and a negative contact, wherein the negative contact of the third output terminal is connected to the third input terminal via a fifth resistor, the positive contact of the third output terminal is connected to the negative terminal of the first output terminal via a sixth resistor;
wherein the first and second input terminals are operable to receive the differential signals of the motherboard, the third input terminal is grounded.

3. A testing apparatus for testing a pair of differential signals of a motherboard, the testing apparatus comprising:
a probe comprising a body and a tip, wherein the tip comprises three input terminals and three output terminals, two of the input terminals are operable to connect two contacts of the motherboard to receive the differential signals, the output terminals are connected to the body; and
an oscillograph connected to the body, wherein the tip is operable to selectively transmit the differential signals from the two contacts of the motherboard to the oscillograph via the body.

4. The testing apparatus of claim 3, wherein the three input terminals and the three output terminals of the tip comprises:
a first input terminal;
a second input terminal;
a third input terminal;
a first output terminal connected to the first input terminal via a first resistor;
a second output terminal connected to the second input terminal via a second resistor, and connected to the first output terminal via a first switch; and
a third output terminal connected to the third input terminal via a third resistor, connected to the first output terminal via a second switch, and connected to the second output terminal via a third switch;
wherein the first and second input terminals are operable to receive the differential signals, the third input terminal is grounded.

5. The testing apparatus of claim 3, wherein the three input terminals and the three output terminals of the tip comprises:
a first input terminal;
a second input terminal;
a third input terminal;
a first output terminal comprising a positive contact and a negative contact, wherein the positive contact of the first output terminal is connected to the first input terminal via a first resistor, the negative contact of the first output terminal is connected to the second input terminal via a second resistor;
a second output terminal comprising a positive contact and a negative contact, wherein the negative contact of the second output terminal is connected to the third input terminal via a third resistor, the positive contact of the second output terminal is connected to the positive contact of the first output terminal via a fourth resistor; and
a third output terminal comprising a positive contact and a negative contact, wherein the negative contact of the third output terminal is connected to the third input terminal via a fifth resistor, the positive contact of the third output terminal is connected to the negative terminal of the first output terminal via a sixth resistor;
wherein the first and second input terminals are operable to receive the differential signals of the motherboard, the third input terminal is grounded.
